(19) United States
(12) Patent Application Publication
(10) Pub. No.: US 2008/0279025 A1
(43) Pub. Date: Nov. 13, 2008

(54) Electronic Circuit with Memory for Which a Threshold Level is Selected

(75) Inventors: Victor Martinus Gerardus Van Acht, Eindhoven (NL); Albert W. Marsman, Eindhoven (NL); Boon Keat Chong, Kuala Lumpur (MY); Nicolaas Lambert, Eindhoven (NL); Pierre Hermanus Woerlee, Eindhoven (NL); Teunis Jan Ikkink, Eindhoven (NL); Aalbert Stek, Eindhoven (NL); Hans Marc Bert Boeve, Eindhoven (NL); Gavin Nicholas Phillips, Eindhoven (NL)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONICS, N.V., Eindhoven (NL)

(21) Appl. No.: 11/568,003

(22) PCT Filed: Apr. 21, 2005
(86) PCT No.: PCT/IB05/51305

§ 371 Date: Oct. 17, 2006

(30) Foreign Application Priority Data
Apr. 22, 2004 (EP) 04101675.9

(51) Int. Cl. G11C 7/02; H03M 7/00

(52) U.S. Cl. 365/207; 341/50

(57) ABSTRACT

A memory (10) is organized as a matrix rows and columns of memory cell circuits (100) and comprises bit line conductors (12) coupled to rows of the memory cells (100). A sensing circuit (14) is coupled to the bit line conductors (12). The sensing circuit (14) is arranged to form respective data signals, each by comparing a respective signal from a plurality of the bit line conductors (12) with a reference level that is common for the bit line conductors (12). A reference level selection circuit (16) with inputs coupled to the plurality of bit line conductors (12) is arranged to control the reference level. The reference level selection circuit (16) selects the reference level dependent on respective analog signal levels on the plurality of the bit line conductors (12), so that analog signal levels from at least respective ones of the plurality of bit line conductors (12) lie on respective sides of the reference level.

The invention relates to an electronic circuit that contains a memory circuit, and more particularly to writing and reading of data in that memory circuit in a way that reduces reading errors. The invention also relates to an encoder for encoding data words for writing into a memory.

Many types of electronic memory circuits are known in the art. An electronic memory circuit contains a matrix of memory cells and bit-lines connected to rows of memory cells. Each cell typically stores a bit of data using some conserved physical quantity that can be affected during writing and sensed during reading. In many programmable memories, such as flash memories for example, the physical quantity is the charge on an electrically isolated electrode, but in other examples the physical quantity can be the magnetization of a piece of magnetizable material, polarization of ferroelectric material, a resistance etc.

Each cell is provided with a conversion mechanism, for producing an electrical signal that depends on the value of the physical quantity. The sensing mechanism supplies the electrical signal to a bit line (the term bit line as used herein will refer to lines that carry signals representing digits, typically binary digits, i.e. bits, but not excluding q-ary digits with q>2). The resulting electrical signal on the bitline is in essence an analog signal, i.e. a signal that may assume any one of a continuous range of values. This is inevitable for memory cells that use analog physical quantities to represent data, but even for cells that store data as discrete states, such as SRAM cells with cross-coupled inverters, the electrical signal on the bitline often has an analog character, because the driving strength of the cells is relatively small compared with other factors that affect the signal on the bitline.

A sensing circuit is connected to the bitlines to convert the analog electrical signal on the bitlines to discrete logical signals, which typically represent which of two discrete logical values has been detected (generally by outputting a signal value from one of two separate ranges). To distinguish whether one logical value or the other should be output, the sensing circuit compares the analog electrical signals on the bitlines with a reference level. Dependent on whether the analog electrical signal on a bit line is above or below the reference level, the sensing circuit outputs a digital signal which represents first or a second logic level respectively.

The reference level must be set carefully, so that factors that are unrelated to the data stored in the cell do not affect the sensing result. In memories with a large signal difference between bitline signals for different logic levels, the reference level can be set at a predetermined level. However, with decreases in memory cell size and increases in the number of cells, or after long retention periods adaptive selection of the reference level may be needed. One solution is to provide reference cells, the output of which is used to determine the reference level. When the properties of the memory cells can vary as a function of position in the memory matrix, a plurality of reference cells may even be provided for different positions in the matrix. The electrical signals from a group of cells associated with a particular reference cell are then compared with the signal from the reference cell. However, this has the problem that data from the entire group of cells may be in error if the reference cell malfunctions. Such a massive error is difficult to correct even if error correction is used.

Among others, it is an object of the invention to provide for an electronic circuit with a memory wherein the reference level for use in the sensing circuit is selected adaptively in such a way that malfunctioning of individual cells only has a limited effect on the sensing result.

Among others, it is another object of the invention to provide for a circuit and method for encoding data words into encoded words wherein a net difference between the number of logical one and the number of logical zero bits in the words is within a predetermined range.

The circuit according to the invention is set forth in claim 1. The invention makes use of data that is stored in memory in words of a plurality of digits. Only words from a selected subset of all possible words are used, selected so that the net difference between numbers of digits (typically bits) at respective logic levels within a predetermined sub-range of the range from zero to the number of bit-lines in the word. On reading a word from the memory, signals from bit line conductors of the memory are compared with a reference level, to form respective digitized output data signals.

The reference level is selected dependent on a combination of the analog signals on the plurality of bit line conductors signals that carry information about the digits in the word, so that the analog signal on at least one of the bit line conductors is on a first side of the reference level and the analog signal on at least another one of the bit line conductors is on a second side opposed to the first side. In a first embodiment, the reference level is selected by averaging the analog signals on the bit line conductors. In a second embodiment the reference level is adapted until the analog signals on at least predetermined numbers of bit lines lie above and below the reference level. Thus, the reference level is selected dependent on the signal levels on a plurality of bit line conductors that carry different digits. As a result the reference level is no longer vulnerable to shifts in the signal level of an individual reference line.

The more bit line conductors for different bits are used, the more robust the reference level selection will be. Preferably, bit line conductors for all bits in a word, or substantially all bit line conductors from a memory matrix are used, e.g. for eight bits, sixty four bits or even a hundred and twenty eight bits or more.

The invention may be applied to memories with cells that output information about binary bit signals on each bit line conductor, but also the memories with cells that output q-ary signals (with q>2). In the latter case at least a pair of successive logic levels is distinguished using a reference level selected dependent on the analog signals from the bit line conductors (which will be called bit line conductors even if they carry signals selected from q levels with q>2).

In an embodiment storage words that are stored in the memory are formed algorithmically on writing a data word to the memory, that is without using prior storage of storage words for all possible data words.

It is a further object of the invention to be able to form encoded words that represent data words so that the number of bits in each encoded word, that have a given logic value, lies within a predetermined range.

It is a particular object of the invention to form such encoded word for uses as storage words for storage in an electronic memory, but more generally it is an object of the invention to form such encoded words for any type of use.

In an embodiment, the encoded words for use as storage words are formed algorithmically, by inverting a subset S of the bits from the data word, but not the other bits of the data word, to form an encoded word. The subset is selected so that a net difference M(S) of numbers of logical zero and logical one bits in the subset is within a predetermined range relative to the total net difference M of numbers of logical zero and logical one bits in the data word as a whole. The subset is for example a subset of bits with successive bit sequence numbers up to a selected sequence number in the word. In an embodiment the range is a range of a predetermined distance above and below half the total net difference. It may be noted that an embodiment of a similar technique for generating data words wherein the net difference M=0 is known per se from U.S. Pat. No. 4,309,694. In this document this technique is not disclosed for the selection of a reference level nor for selecting a larger set of data words where M is near zero, but not necessarily zero.

These and other objects and advantageous aspects of the invention will be described using examples from the accompanying figures

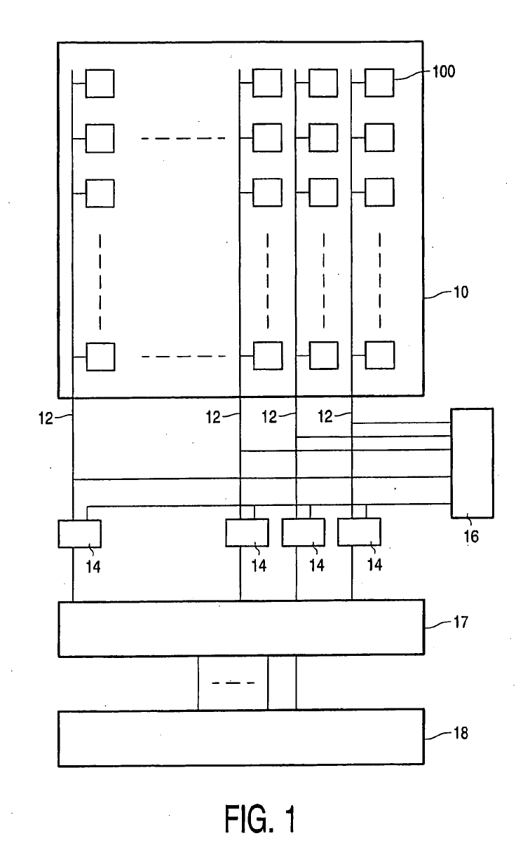

FIG. 1 shows a circuit with a matrix of memory cells

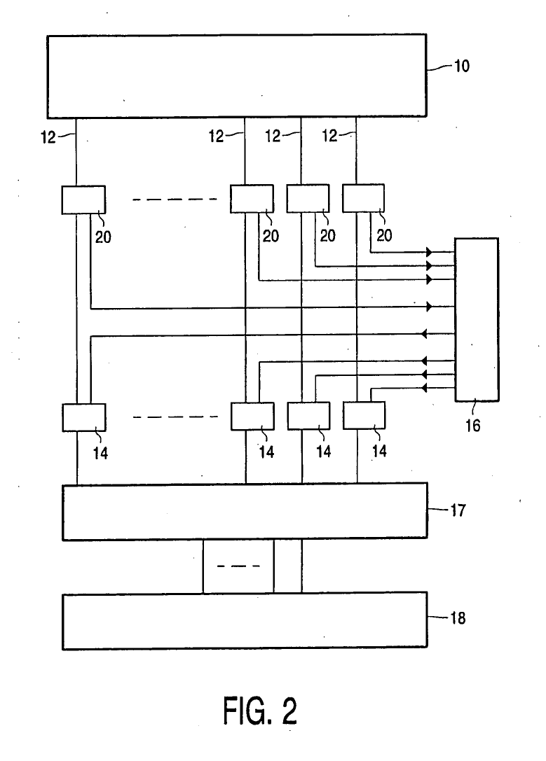

FIG. 2 shows an alternative circuit with a memory

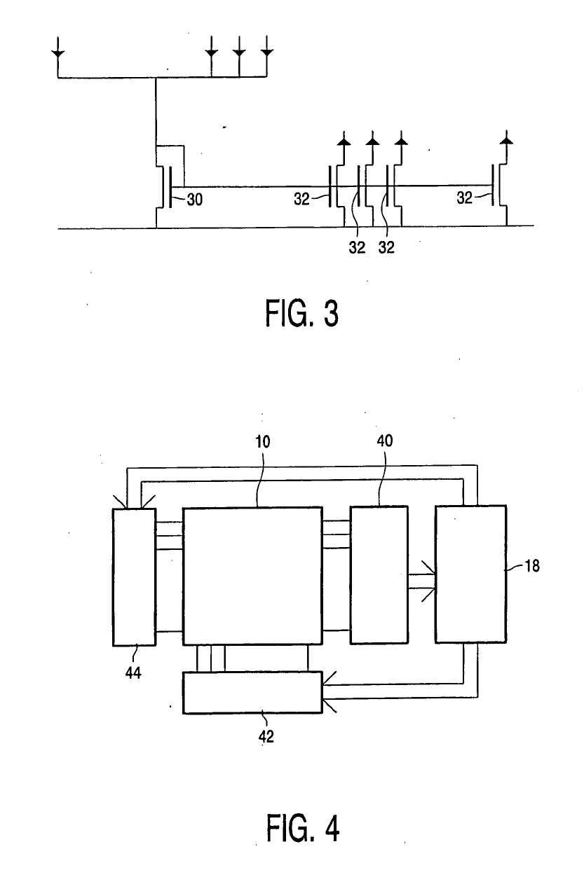

FIG. 3 shows a reference level selection circuit

FIG. 4 shows a circuit with a matrix of memory cells and a writing circuit

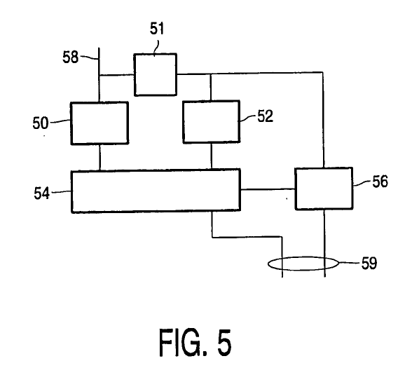

FIG. 5 shows a data word translation circuit

FIG. 1 shows an electronic circuit with a memory 10, bit line conductors 12, sense amplifiers 14, a reference level selection circuit 16, a word conversion circuit 17 and processing circuits 18. Memory 10 comprises a matrix of rows and columns of memory cells 100 (only one provided with a reference numeral). Each column of cells 100 is coupled to a respective bit line 12. Bit line conductors 12 are coupled to first inputs of respective sense amplifiers 14 and to inputs of reference level selection circuit 16. Reference level selection circuit 16 has an output coupled in common to second inputs of sense amplifiers 14. Sense amplifiers 14 has outputs coupled to processing circuits 18, via word conversion circuit 17. Typically, the entire circuit of FIG. 1 is integrated in a single semi-conductor integrated circuit.

In operation, each memory cell 100 stores information about a respective binary value in the form of a value of an analog physical property. For example in the form of an amount of charge present on an electrically isolated electrode, or in the form of a magnetization of a piece of magnetic material, etc. When the information has to be read a plurality of cells 100, for example from a row of cells or a part of a row, is selected by an addressing circuit (not shown). In response, the selected cells apply information dependent electrical signals, for example in the form of voltages on bit-line conductors 12.

FIG. 2 shows an alternative embodiment wherein the electrical signals from the cells are currents on bit line conductors 12. In this embodiment current copying circuits 20 have been added between bit line conductors 12 and reference level selection circuit 16 and the first inputs of sense amplifiers 14. Reference level selection circuit 16 supplies respective, mutually equal reference currents to the second inputs of sense amplifiers 14.

Current copying circuits 20 may be implemented for example as two-output current mirror circuits.

Sense amplifiers 14 may be of any suitable type, containing for example differential amplifier circuits, cross-coupled amplification circuits (as used for DRAMs), current mode sense amplifiers etc.

Reference level selection circuit 16 receives the electrical signals (currents and/or voltages) and under control of these signals selects a reference level. Reference level selection circuit 16 applies the reference level to the second inputs of sense amplifiers 14, which compare the electrical signals on respective bit line conductors 12 with the reference level and output logic one or zero signals, dependent on whether the electrical signals on bit line conductors 12 are above or below the reference level respectively. Conversion circuit 17 translates the combination of logic ones and zeros from sense amplifiers 14 into a translated data word. Processing circuits 18 use the translated data word for a data processing function that is particular to the circuit.

In a first embodiment reference level selection circuit 16 determines an average of the electrical signals on bit line conductors 12 to determine the reference level. This is based on the content of the bits in words that are stored in memory 14. A word is defined by the content of cells 100 that apply electrical signals in parallel to sense amplifiers 14 when a memory address is selected. All addressable words in memory 10 are selected from a subset of possible words, so that each word contains substantially as many logical ones as zeros. For example, in case of nine bit words there are 420 words with between three and six logical ones. 256 of these words may be selected for use to represent 8-bit data words data in memory 10.

When each bit for such a word is programmed the physical property (charge, magnetization etc.) is nominally set to respective different values in the case of a logical one or zero respectively. If these nominal values result in a bit line signal value of A1 or A0 (A1>A0) during reading respectively, then, the average of the bit lines lies between

(min*A1+(n−min)*A0)/n≦Average≦(max*A1+(n−max)*A0)/n

(herein “n” is the number of bits in the word, “min” is the minimum number of bits in any of the words with the value of logic one and “max” is the maximum number of bits in any of the words with the value of logic one). The particular average depends on the specific word that has been programmed into the memory. Any value in this range may be used as reference level. During sensing this ensures a margin of at least min*(A1−A0)/n for logic zeros and a margin of (1−max/n)*(A1−A0) for logic ones. That is, in the example of n=9, with min=3 and max=6, there is a margin of (A1−A0)/3 between the selected reference level and both logic zeros and ones. As the word size n becomes larger, a larger margin can be realized. In another example, when n=33 and min=15 and max=18 one can store 32 user bits and there is a margin of (A1−A0)*15/33 on both sides which is already almost equal to the full margin (A1−A0)/2.

Due to errors or physical effects the analog signal on a bit line conductor 12 may shift from the nominal values A1, A0. Common shifts of signals on all bit line conductors 12 that carry a logic one, or another common shift on all bit line conductors 12 that carry a logic zero, or both, do not affect the sensing result, as long as the signal levels for logic ones and zeros remain distinguishably apart.

Errors may arise only if there are mutually different shifts in the signals-on bit line conductors 12 that represent the same logic signal. The error margins for a shift of this type in a single signal are more than (1−max/n)*(A1−A0) and min*(A1−A0)/n. These margins can be adapted by using a set of storage words with adapted values of max and min. Selecting max and min further from n and 0 respectively increases the margins, but reduces the number of available words. The margins are preferably set to the minimum level that is needed to prevent errors due to specified allowable shifts in the logic one and zero levels.

FIG. 3 shows an embodiment of reference level selection circuit 16 for use in the circuit of FIG. 2. The reference level selection circuit 16 comprises a multi-output current mirror with an input/output factor of 1/n, input currents from being fed to a common input transistor, which mirrors the sum of the input currents, divided by n, through output transistors 32 to the second inputs of sense amplifiers 14 (not shown). The input output factor is realized for example by making the input transistor n times as wide as the output transistor, or by using n input transistors of the same size as the output transistors in parallel. Of course, averaging can also be realized for voltage output signals, using for example a summing circuit with a plurality of resistors coupled between bit line conductors 16 and a summing node and a buffer amplifier coupled between the summing node and the second inputs of sense amplifiers 14.

The use of the average as reference level is robust against collective shifts of the signal level A1 corresponding to logic ones and/or collective shifts of the signal level A0 corresponding to logic zeros. When the differences between the individual shifts in the levels of different bits in the words are within a margin this scheme is also robust against individual shifts.

In a further embodiment the signals from bit line conductors 12 may be clipped before taking the average, so that bit lines conductors that carry excessively large signals do not contribute more than a maximum and/or no less than a minimum to the average. More generally, saturation may be used, taking an average of the results of applying an S-shaped saturating function to the signals from the bit line conductors (Saturating, as used herein, includes clipping. By definition the slope of a saturating function decreases as a function of the distance of the signals to the most sensitive (normal) range), so that the ratio between the contribution to the sum and the signal is less as the signal is deviation from the normal range decreases, even if the contribution itself still increases.). For this purpose clipping or saturating circuits (not shown) may be inserted between bit line conductors 12 and the inputs of reference level selection circuit 16, i.e. circuits whose output signal vary as a function of their input signals, but wherein the sensitivity for variation of the input signal decreases, or even disappears, when the input signals are beyond a maximum and/or minimum.

It should be appreciated that, without deviating from the invention, different mechanisms may be used for selecting the reference level. For example, in another embodiment, reference level selection circuit 16 starts from an initial reference level, detects the number of bit line conductors 12 that carry a signal above the initial reference level and adapts the reference level until the number of the number of bit line conductors 12 that carry a signal above the initial reference level is between the and min and max values for the words that have been stored. When reference level selection circuit 16 detects that the number of logic levels that corresponds to higher signals on bit line conductors is lower than the minimum in any word it increases the reference level. When reference level selection circuit 16 detects that the number of logic levels that corresponds to higher signals on bit line conductors is higher than the maximum in any word it decreases the reference level.

Preferably, in this embodiment, reference level selection circuit 16 continues to adapt the reference level until the number of logic levels that corresponds to higher signals on bit line conductors is higher than or equal to a first number, which is higher than the minimum number of such bits in any word and lower than or equal to a second number which is lower than the minimum number of such bits in any word. Thus, a better robustness against errors is realized. Preferably the first and second number are both substantially equal to the average of the maximum and the minimum.

Compared to averaging this approach has the advantage that it is less sensitive to outliers, and the disadvantage that it may be less robust because the reference level may lie close to a signal on a signal conductor, which makes detection sensitive to noise. Moreover, counting of numbers of bits generally takes more time than averaging, making the memory slower.

In an embodiment, reference level selection circuit 16 receives the output signal of sense amplifiers 14 and not their input signals to select the reference level by adapting the reference level and observing the resulting number of bits of different logical values. In another embodiment reference level selection circuit 16 contains its own sense amplifiers for this purpose.

This embodiment is slower than the method that uses the average as reference level, but it has the advantage that it is robust against extreme variations in deviations of the signal levels of some bits, which could shift the average to a value that is useless as reference level. Reference level selection is robust against common shifts of the levels of the signals on bit line conductors 12 that represent the same logic level (as longs as the logic one and zero levels do not cross), and against differences in the shifts of signals on individual bit line conductors, provided that no more than max-min bits shift more than the difference between the logic one and zero levels. Preferably max and min for the set of storage words are selected so that this type of shift for a specified number of bit line conductors 12 may be compensated for. Of course, in the event of such shifts, the bits that are involved may be detected erroneously, even though the reference level is selected properly for other bits. However, such errors affect individual bits which can be corrected by means of known error correction techniques.

During the selection of the reference level, the number of bit line conductors 12 that carry a signal above the initial reference level may be computed by a digital counting circuit, but instead an analog circuit may be used. For example an analog sum signal may be formed of output signals of sense amplifiers that output digital results of comparison of signals on bit line conductors 12 with a reference level. This analog sum signal may be applied to analog comparators, to compare the sum signal with a minimum and a maximum. The outputs of such comparators may be used to control the direction of adaptation of the reference level and/or to signal that a suitable reference level has been found. In this way a continuous adaptation may be realized, but the adaptation may also be performed in steps.

As another alternative, reference level selection circuit 16 may be arranged to test a plurality of predetermined potential reference levels (in parallel and in series) and to detect how many of the signals on bit line conductors 12 lie above and/or below each tested reference level. In this embodiment reference level selection circuit 16 may select one of the potential reference levels or a combination on the basis of the detected numbers. This too can be realized by means of digital counting or analog summing.

Furthermore, it will be appreciated that the use of the average is based on an embodiment wherein the difference between the number of logical ones and zeros in all words in memory 10 is within a predetermined range around zero. In another embodiment words are used wherein said difference is within another predetermined range for all words. In this type of embodiment reference level selection circuit 16 may be arranged so that the difference between the number of logical ones and zeros at the outputs of sense amplifiers 14 is within the other predetermined range.

Although an embodiment of the invention has been described wherein signals from all bit line conductors 12 from memory have been used to determine the reference level, it should be understood that in an embodiment a reference level determined from signals from only part of bit line conductors 16 may be used for other bit line conductors 12 as well. As long as the content of memory 16 is arranged so that the difference between the number of logical ones and the number of logical zeros in the collectively addressable cells that are connected to the relevant part of the bit line conductors 12, the reference level that is obtained can be used to detect information from both the relevant part of the bit line conductors 12 and all other bit line conductors 16.

In a further embodiment memory 10 contains cells that can be programmed to more than two levels, e.g. to four levels. Thus, more information can be stored per cell in memory 10. In this embodiment, comparison with a plurality of reference levels is used to digitize the output signals from bit line conductors 12. In accordance with the invention, at least one of these reference levels and preferably all reference levels are selected dependent on the signal level of a plurality of bit line conductors 12 that also carry data information.

In one embodiment data is programmed in memory 10 so that the physical quantity in each cell is nominally programmed to one of q (q>2) programmable levels. Words are programmed into the memory, information units from each word being stored in “n” cells. Each information unit may assume one of q possible values. Each cell stores one information unit, represented by which of the q programmable levels is programmed in the cell. The words are selected so that each word contains at most a first number n1 of information units that correspond to programming levels equal to or lower than a particular one of the programming levels and at most a second number n2 of information units that correspond to programming levels higher than the particular one of the programming levels.

In this embodiment the reference level to distinguish between the particular one of the programming levels and the next higher programming level is selected dependent on the output signals from the cells that are connected in parallel to the bit lines in response to a common address. The reference level is adapted until the number “x” of cells for the word that output signals below the reference level is smaller than n1 and larger than n−n2. Similar techniques may be used to determine other reference levels.

In another embodiment, the words are selected from a sub-set of words for which the average of the nominal output of the cells of the word is always between the output signal for a particular one of the programming levels and the next. In this embodiment the reference level to distinguish between the particular one of the programming levels and the next higher programming level is selected by averaging the output signals from the cells that are connected in parallel to the bit lines in response to a common address. As in the case of two-level data, clipping may be used to reduce the effect of extreme output signal deviations. In this embodiment, further reference levels may be selected for example, from the average of the output signals at a sub-set of bit lines where the output signals are on the same side of the first determined reference levels. Such a selection mechanism works if words from a suitable set of words is used, wherein the average of the nominal output of the cells for this subset is always between the output signal for another programming levels and the next.

In the case of three level encoding, codewords may be used in which twice the number digits with the highest level equals the sum of the number of digits of the remaining levels. In this case a special form of ‘clipping’ may be used. In this case the high clipping level for the ‘high’ reference level is twice the ‘low’ clipping level.

During operation of the circuit processing circuits 18 typically read and write arbitrary words of data, that is, not necessarily only words that satisfy the conditions needed for selection of the reference level (or levels). If this is the case translator circuits are preferably provided to translate data words from processing circuits 18 to storage words for memory 10 and vice versa.

FIG. 4 shows a circuit that is also able to write data to memory 10. The sensing circuit is designated by reference numeral 40. In addition an addressing circuit 42 and a write translation circuit 44 coupled to memory 10 are provided. Processing circuits 18 have an address output coupled to addressing circuit 42 and a data output coupled to write translation circuit 44. In operation, write translation circuit 44 assigns each possible word that it receives from processing circuits 18 into a respective storage word wherein the number of bits that have a logical one value is between a predetermined minimum and maximum. Addressing circuit 42 addresses memory 10 and causes memory 10 to store the storage word at an addressed location.

However, it should be appreciated that writing is not necessary for the invention. In another embodiment memory 10 is a read only memory wherein the content of the cells is programmed once, for example during manufacture, with storage words that meet the required condition.

Any scheme may be used to assign storage words to data words from processing circuits 18 and vice versa. In one embodiment lookup table memories are used for translation. A first lookup table memory in write translation circuit 44 is addressed by data words from processing circuits 18 and the addressed locations in the lookup table memory contain the associated storage words. Similarly, a second look up table memory in read translation circuit 16 is addressed by storage words and the addressed locations in the lookup table memory contain the associated data words for use by processing circuits 18. In this embodiment the storage words and the relation between storage words and data words may be hand picked from storage words that meet whatever condition is necessary for selection of the reference level (or levels). The function of the lookup memory may also be realized by means of logic circuits that implement the input/output relation defined by the table in the look-up memory.

However, the translation by means of circuits with a look-up memory function has the disadvantage that additional memory circuits are needed. Also, the lookup memory may cause disadvantageous reading and/or writing delays.

In another embodiment the storage words are selected algorithmically. Several schemes may be used. In one scheme the storage word is formed from the data word by copying a selected first part of the bits of a data word and copying the logical inverse of the remaining bits into the storage word. The parts are selected so that the resulting storage word meets the conditions on the storage word. Additional information is added to indicate which part of the bits has been inverted and the additional bits are added to the storage word.

For example, the bits of the data words may be assigned sequence numbers “i”, and the bits with sequence numbers up to a selected sequence number “j” may be copied into the storage word, the remainder being inverted. In this case the additional information represents the selected sequence number. In an embodiment wherein the n-bits of each storage word that derives from a data word should contain n/2 bits with the value of logic one and n/2 bits with the value of logic zero, the sequence number j may be selected as follows. First write translation circuit 44 determines the total net number M of bits in a data word, that is the difference between the numbers of bit that that have the value of logical one and zero respectively. Next, write translation circuit 44 counts the partial net number M(k), which is the difference between the numbers of bits with sequence numbers up to a running sequence number “k”, as a function of the running sequence number k, that have the value of logical one and zero respectively. Write translation circuit 44 selects a running sequence number j for which 2*M(j)=M and copies the bits with sequence numbers up to the selected sequence number “j” into the storage word, the bits with higher sequence numbers being inverted. Due to partial inversion, the total net number for the partially inverted word becomes

2*M(j)−M

With the selection of the sequence number so that 2M(j)=M it is ensured that the net sum is zero. This algorithm has been described in U.S. Pat. No. 4,309,694, which produces codewords with a net sum of zero. However in the present invention the ‘pointer’ may be selected with to reduced accuracy (e.g. by leaving out a few LSBs), and in this case a ‘nearly DC-free’ code words is obtained with guaranteed maximum inaccuracy. For the determination of the reference level, this is good enough.

FIG. 5 shows a write translation circuit according to this embodiment. The write translation circuit contains a total bit counter 50, a register 51, a running bit counter 52, a selection circuit 54 and an inversion circuit 56. An input 58 from the data processing circuits (not shown) is coupled to total bit counter 50 and via register 51 to inversion circuit 56 and running bit counter 52. Total bit counter 50 and running bit counter 52 have outputs coupled to selection circuit 54. Selection circuit 54 has outputs coupled to inversion circuit 56 and a storage word output 59. Inversion circuit 56 also has an output coupled to storage word output.

In operation a data word is applied to input 58. Total bit counter 50 counts a total net number M of bits in the data word. Register 51 stores the data word and supplies the bits of the data word serially to running bit counter 52 and inversion circuit 56. Running bit counter 52 counts and outputs counts of the partial net numbers M(k) of bits for bit sequence numbers k. Selection circuit 54 selects a bit sequence number j for which 2*M(j)=M and outputs a binary representation of the selected sequence number j to output 59 and inversion circuit 56. Inversion circuit 56 passes the bits of the data word to output 59, inverting the bits that have a higher sequence number than the selected sequence number.

In the embodiment, running bit counter 52 and inversion circuit 56 operate bit-serially and in synchronism, successive bits of the data word being applied to both. Running bit counter 52 maintains a count of the partial net number of bits for the bits that have been applied and selection circuit 54 generates a pulse signal to inversion circuit 56 when the count equals M/2 (from the output of total bit counter). Inversion circuit 56 passes the successive bits of the data word unmodified until it receives the pulse signal and subsequently it passes the bits inverted. However, without deviating from the invention, more complicated counting and inversion circuits may be used, which determine the count and control inversion on the basis of bits that are supplied in parallel.

In an embodiment wherein n-bits of the storage word that derives from a data word should be a net number (difference between number of logic one bits and number of logic zero bits) between 2 m and −2 m, selection circuit 54 selects such a sequence number k for which

−m<M(k)<m

To find such a sequence number it suffices to consider a subset of the sequence numbers that are 2*m sequence numbers apart. In this embodiment, running bit counter 52 and inversion circuit 56 may input successive groups of 2 m bits in synchronism. Running bit counter 52 maintains a count of the partial net number M(k) of bits for the groups bits that have been applied and selection circuit 54 generates a pulse signal to inversion circuit 56 when the count is in the range described above. Inversion circuit 56 passes the successive groups bits of the data word unmodified until it receives the pulse signal and subsequently it passes the groups of bits inverted.

Since the total net number obtained by inverting the data word from the bit with sequence number k is 2M(k)−M, this technique may be generalized further if a data word should contain a net number of bits between m1 and m2, simply by searching for a bit sequence number such that

m1+M<2M(k)<m2+M

As will be appreciated counting the net number M(k) of bits successively for different sequence numbers k can take considerable time if it is performed sequentially. In an embodiment total bit counter 50 supplies partial sums M(k) during the computation of the total net number M and selection circuit 54 searches for a “k” value on the basis of the supplied sums.

The bits of the data word (partially inverted and partially not inverted) and the additional bits that denote the selected sequence number j are written cells of memory 10. During reading, both the bits of the data word and the additional information are read together. The reference level is selected (preferably using the bits of the data word only, without using the bits of the additional information) and the bits are digitized using the selected threshold. Next part of the bits is inverted, under control of the additional information, so that the original data word is recovered.

Although the formation of the storage word is preferably performed digitally it should be appreciated that in an embodiment at least part may be performed by analog signal processing. For example, the computation of the net numbers M, M(k), or other numbers that carry the same information, may be realized by analog summing of signals (e.g. currents) that are determined by the bits of the data word. The resulting analog sum signals may be compared according to the inequalities described in the preceding and used to control adaptation of the sequence number k. This makes it possible to process the bits in parallel at higher speed.

Although the selection of the storage words has been described for the purpose of generating words for storing data in memory 10, it will be understood that the same technique can be applied, independent of storage, or indeed the particular selection of the reference level.

Although the invention has been described with the aid of specific embodiments, it should be appreciated that the invention can be implemented in other ways. For example it should be clear that the role of logic ones and zeros may be exchanged. Similarly, it should be appreciated that the plurality of bits that is used to select the reference level can contain any number of bits, provided that storage only words are used that contain the required net number of bits. A trivial case occurs if two bit words are used, since this corresponds to a bit of differential data. Similarly use of words that contain bit pairs that can programmed only to logical 10 or 01 is a very simple implementation, wherein according to the invention output signals from all bit pairs are used to select one reference level for all bit pairs. However, such simple choices of the set of storage words significantly limit the number of possible storage words. Preferably, the set of storage words contains not just words wherein bits in predetermined pairs of bits have mutually opposite logical values, but also different words wherein substantially any pair of bits may have the same first value, the same second value or mutually opposite value.

Furthermore, although embodiments have been described wherein signals from all bit line conductors 12 of the memory that are output in parallel are used to determine the reference level, it should be understood that without deviating from the invention also signals from only part of these bit line conductors may be used, the resulting reference level being used for all bit line conductors, also those that have not been used to determine the reference level. In this case, the words stored in cells that connect to the part of the bit lines conductors that are used to determine the reference level should substantially meet the specified conditions on the net number of bits.

In some embodiments the words may be structured so that plural groups of bits that are output in parallel each meet the conditions that enable the selection of a reference level. In this case, a reference level from any one or combination of the groups may be used. The circuit may be arranged to select a group for the determination of the reference level during reading, for example to prevent that errors in one group prevent determination of a suitable reference level from that group.

Although not described, it should be understood that any error correction technique may be applied to the bits produced by sense amplifiers 14′. For example, the storage words may be selected from an ECC (Error Correcting Code), e.g. by storing, additional parity bits, and the results produced by sense amplifiers 14 may be corrected using the knowledge that words from the ECC were stored. Techniques to do so are known per se. In this way, errors in the signals on any limited number of bit line conductors 12 can be corrected. At the same time such errors do not affect the selection of the reference level, provided that the words from the memory ensure sufficient margin, i.e. that they ensure that the selected reference level still distinguishes between adjacent logic levels for bits on bit line conductors 12 even if some bits are in error.

Although the invention has been described using dedicated circuits to perform detection, it will be understood that at least part of the required processing may be performed by suitably programmed programmable processors. Thus, for example the selection of storage words may be performed by execution of a program, or the selection of a direction in which to modify the reference level, or the selection of the reference level from a number of tested reference levels.

1. An electronic circuit, comprising
a memory (10) that is organized as a matrix rows and columns of memory cell circuits (100) and comprises bit line conductors (12) coupled to rows of the memory cells (100);
a sensing circuit (14) coupled to the bit line conductors (12), the sensing circuit (14) being arranged to form respective data signals, each by comparing a respective signal from a plurality of the bit line conductors (12) with a reference level that is common for the bit line conductors (12);
a reference level selection circuit (16) with inputs coupled to the plurality of bit line conductors (12) and arranged to control the reference level, the reference level selection circuit (16) being arranged to select the reference level dependent on respective analog signal levels on the plurality of the bit line conductors (12), so that analog signal levels from at least respective ones of the plurality of bit line conductors (12) lie on respective sides of the reference level.

2. An electronic circuit according to claim 1, wherein the reference level selection circuit (16) is arranged to form an average of the analog signal levels from the plurality of the bit line conductors (12) and to control the reference level using the average.

3. An electronic circuit according to claim 2, wherein the reference level selection circuit (16) is arranged to form the average from saturation function of the analog signal values.

4. An electronic circuit according to claim 1, wherein the reference level selection circuit (16) is arranged to detect information indicative of one or more counts of bit line conductors (12) that carry analog signals below a test level or respective test levels, and to select the reference level on the basis of said count or counts so that a further count of bit line conductors (12) that carry analog signals below the reference level lies between a first and second predetermined number.

5. An electronic circuit according to claim 4, wherein the reference level selection circuit (16) is arranged to
set the reference level to an initial level;
determine a count which is indicative of an observed number of bit line conductors (12) from the plurality whose analog signal level lie below the reference level;
adjust the reference level in an upward or downward direction when the count indicates that said actual number is below the first predetermined number or a above the second predetermined number respectively, until the observed count is equal to or above the first predetermined number and the equal to or below the second predetermined number.

6. An electronic circuit according to claim 1, wherein the memory matrix (10) stores words of multiple digits, each digit for output on a respective one of the plurality of bit line conductors (12), each word containing a respective number of digits with a first logic level, the respective numbers for all stored words being greater than zero and smaller than the total number of digits in the plurality.

7. An electronic circuit according to claim 1, comprising a write circuit (44), with a data word input and a storage word output coupled to the memory (10), the write circuit (44) being arranged to select storage words to encode received data words for application to the storage word output, the write circuit (44) selecting the storage words from a collection that contains only words wherein a number of digits with a first logic level in each stored word is equal or greater than zero and smaller than the total number of digits in the plurality.

8. An electronic circuit according to claim 7, comprising
a partial inversion circuit (56) with an input coupled to the data word input (58), an output coupled to the storage word output (59) and a control input, the partial inversion circuit (56) being arranged to form the storage word from digits of the data word, so that a subset of digits is inverted and a remainder of the digits is uninverted in the storage word relative to the data word, the subset being selected under control of a selection signal from the control input;
a selection signal computation circuit (50, 51, 52, 54) with an input coupled to the data word input (58) and arranged to generate the selection signal, so that a partial net difference between numbers of digits in the selected subset at respective logic levels lies within a predetermined range relative to a total net difference between the numbers of digits in the data word as a whole at the respective logic levels.

9. An electronic circuit according to claim 8, wherein the selection signal computation circuit (50, 51, 52, 54) is arranged to compute information that is indicative of the partial net difference incrementally for successive parts of the data word, successively incrementing the parts by adding groups of at least one digit from the data word to preceding parts, until a successive part with a net number within the predetermined range is encountered, the partial inversion circuit being arranged to invert successively either the digits from the successive parts up to the encountered part, or the remaining digits.

10. A method of reading data from a matrix organized memory with memory cells (100), the method comprising
selecting memory cells (100) that store a word of a plurality of digits, each selected memory cell (100) storing a respective digit;
receiving output signals from the selected cells (100);
selecting a reference level dependent on respective analog signal levels from the selected memory cells (100), so that analog signal levels from respective groups of the selected memory cells (100) lie on respective sides of the reference level;
comparing the analog signal levels of signals from cells in the plurality with the selected reference level, to form digitized data signals;
processing digital data words formed by said digitized data signals.

11. An encoding circuit with a data word input and an encoded word output, the encoding circuit comprising
a partial inversion circuit (56) with an input coupled to a data word input (58), an output coupled to the encoded word output (59) and a control input, the partial inversion circuit (59) being arranged to form digits of an encoded word at the encoded word output (59) from digits of a data word supplied from the data word input (58), so that a subset of bits is inverted and a remainder of the bits is uninverted in the encoded word relative to the data word, the subset being selected under control of a selection signal from the control input;
a selection signal computation circuit with an input coupled to the data word input (58) and arranged to generate the selection signal, the selection signal computation circuit (58) being arranged to compute information that is indicative of the partial net difference incrementally for successive parts of the data word, successively incrementing the parts by adding groups of at least two digits from the data word to preceding parts, until a successive part with a net difference between numbers of digits at respective logic levels in the part is encountered, where the net difference lies within a predetermined range relative to a total net difference between the numbers of digits at the respective logic levels in the data word as a whole, the predetermined range comprising at least two possible net difference values, the partial inversion circuit being arranged to invert successively either the digits from the successive parts up to the encountered part, or the remaining digits.

12. A method of encoding a data word, the method comprising
receiving digits of the data word;
selecting a subset of the digits, so that a partial net difference between numbers of digits at respective logic levels in the selected subset lies within a predetermined range relative to a total net difference between numbers of digits at the respective logic levels in the data word as a whole, the range comprising at least two possible net difference values, said selecting comprising computing information that represents the partial net difference incrementally for successive parts of the data word, successively incrementing the parts by adding groups of at least two digits from the data word to preceding parts, until a successive part with a net number within the predetermined range is encountered.
forming the encoded word from digits of the data word, so that the selected subset of bits is inverted and a remainder of the digits is uninverted in the encoded word relative to the data word.
